(19) United States
(12) Patent Application Publication
(10) Pub. No.: US 2007/0269924 A1
(43) Pub. Date: Nov. 22, 2007

(54) Patterning nanowires on surfaces for fabricating nanoscale electronic devices

(75) Inventors: Marcos Gomez, Santa Barbara, CA (US); Frauke Richter, Munchen (DE); Peter Erk, Frankenthal (DE); Zhenan Bao, Stanford, CA (US); Shuhong Liu, Stanford, CA (US)

Correspondence Address: OBLON, SPIVAK, MCCLELLAND MAIER & NEUSTADT, P.C., 1940 DUKE STREET, ALEXANDRIA, VA, 22314, US

(73) Assignee: BASF Aktiengesellschaft, Ludwigshafen (DE)

(21) Appl. No.: 11/435,886

(22) Filed: May 18, 2006

(51) Int. Cl. H01L 21/44

(52) U.S. Cl. 438/99; 438/677; 977/887; 977/892

(57) ABSTRACT

The present invention relates to a method of depositing nanowires on the surface of a substrate, comprising the steps of:
contacting defined regions of the substrate with at least one compound (C1) capable of binding to the surface of the substrate and of binding the nanowires to provide a pattern of binding sites on the surface of the substrate and/or contacting defined regions of the substrate with at least one compound (C2) capable of binding to the surface of the substrate and preventing the binding of nanowires to provide a pattern of non-binding sites on the surface of the substrate, and
contacting the surface of the substrate with a suspension of nanowires in a liquid medium to enable at least a portion of the applied nanowires to bind to at least a portion of the surface of the substrate covered with (C1) and/or not covered with (C2).

### BACKGROUND OF THE INVENTION

1. Field of the Invention

The present invention relates to a method of depositing nanowires on the surface of a substrate.

2. Description of the Related Art

In the field of microelectronics there is a constant need to develop smaller device elements that can be reproduced conveniently and inexpensively with a lowest possible failure rate. Lithographic techniques for the manufacture of integrated circuits (ICs) are well known in the art. However, the smaller the device, the more difficult and, as a result, the more expensive it is to manufacture. Moreover, in the production of semiconductors on a molecular scale, lithographic approaches may fail owing to lithographic constraints imposed by resolution and alignment. It is therefore desirable to produce ICs by techniques which use a driving force that causes circuitry to assemble in the desired fashion (self-assembling of electronic circuitry).

One-dimensional nanostructures, such as nanowires, are the smallest known dimensions for efficient transport of electrons and potential tools for hierarchical assembly of nanoscale electronics. A future approach therefore involves using conducting or semiconducting nanowires as the building blocks for large area electronic and optoelectronic devices. Recently, the fabrication of nanowires has been explored, owing to its potential importance as a building block in nano, microelectromechanical (MEM), and nanoelectromechanical NEM device applications. For example, current approaches suggest the use of a variety of semiconductor nanowires made from materials such as silicon (Si), Si—Ge, InP, and GaN in building nano-computing system. Metallic nanowires are of potential interest as interconnections and the sharp tips of the nanowire make them effective for field emission purpose.

Different methods for the self-assembly of essentially one-dimensional micro-objects onto substrates are known. A first self-assembly technique makes use of the patterning of objects through applied electric or magnetic fields. The electrical or magnetic contacts of the substrates were prefabricated. By adding an external electric or magnetic field, objects could be aligned or placed in certain regions of the substrates.

A further self-assembly technique makes use of fluidic alignment, wherein one-dimensional objects are employed that match receptor sites or “holes” that have been etched into the substrate. The objects are suspended in a carrier liquid that is dispensed over the substrate and fall towards the receptor sites with the assistance of liquid flow. The driving force behind this assembly process is the shear force of the fluid. In order to control the flow direction microchannels can be designed.

Yu Huang, Xiangfeng Duan, Qingqiao Wei and Charles M. Lieber describe in Science, 2001, 291, 630-633, the directed assembly of one-dimensional nanostructures into functional networks. Nanowires were assembled into parallel arrays by combining fluidic alignment with surface-patterning techniques. Semiconducting nanowires were synthesized by laser-assisted catalytic growth and suspended in an ethanol solution. Assembled arrays were obtained by passing the suspension through fluidic channel structures formed between a poly(dimethylsiloxane) mold and a flat substrate. Parallel and crossed arrays could be achieved with single and sequential crossed flows, respectively. This document does not teach the use of microcontact printing (“stamping”) to form a binding pattern on the surface of the substrate, allowing alignment of the nanowires on the substrate.

A further self-assembly technique makes use of mechanical stretching. According to this method, one-dimensional objects incorporated into polymer films can be orientated with their longitudinal axes in the direction the polymer is stretched.

A further self-assembly technique makes use of surface interactions. To obtain modifications, substrate surfaces can be patterned into regions with different chemical functionality and/or positive/negative charges. Thus, e.g. a substrate can be patterned into hydrophobic/hydrophilic regions or into regions with positive and/or negative charges. Micro-objects that also have a modified surface can be patterned into selected regions through chemical interaction, electrostatic force or biomolecular interaction.

A further self-assembly technique makes use of Langmuir-Blodgett interactions (LB technique). The surface of one-dimensional objects can be functionalized with organic molecules (e.g. bearing long alkyl chains) and then the objects dispersed in a suitable solvent. This dispersion can be spread dropwise onto a subphase surface. The objects form a monolayer on the air-water interface, which is slowly compressed. This monolayer can be transferred during/after the compression process onto another substrate. One-dimensional objects can be aligned by this process.

A further self-assembly technique makes use of electrospinning. According to this approach, one-dimensional objects are mixed with polymer solutions to achieve viscoelastic spinnable solutions. The electrospinning technique is based on electrostatic forces. A jet of the polymer solution, which experiences high extension owing to an electrostatically caused instability forms thin nanofibers. The one-dimensional nanostructures were first aligned by a sink flow and subsequently by the high tension of the electrospun jet.

A further self-assembly technique makes use of in situ growth. The sites of growth and/or growth directions of one-dimensional nanostructures can be controlled by using templates such as DNA, nanopores or step-edges or by application of external electric fields.

US 2004/0061104 A1 discloses a method for making an integrated circuit (IC) in which organic semiconductor crystallites function as active channels in organic semiconductor devices. The method includes providing a substrate with a surface that has a preselected pattern of adhesion sites located thereon and is capable of adhering crystallites of an organic semiconductor. This document does not teach the use of microcontact printing (“stamping”) to form a semiconductor pattern on the surface of the substrate.

Unpublished co-pending U.S. application Ser. No. 11/353,934 discloses a method of patterning the surface of a substrate with at least one crystalline compound, comprising the step of depositing on the surface of the substrate at least one compound (C1) capable of binding to the surface of the substrate and of binding at least one crystalline compound and/or at least one compound (C2) capable of binding to the surface of the substrate and preventing the binding of a crystalline compound.

The patterning methods according to the prior art show at least one of the following disadvantages:
high cost and/or low throughput (e.g. in order to align objects through applied electric or magnetic fields, the necessary electrical or magnetic contacts of the substrates have to be prefabricated by known patterning techniques. The production of a substrate pattern on a molecular scale involvess sophisticated and expensive techniques such as optical or electron beam lithography to make substrate patterns.)
complexity (several process steps and/or special instrumental equipment is required, e.g. for patterning by in situ growth)
no general applicability (e.g. high demands on surface properties (chemical, electric, magnetic modification) and dimensions of micro-objects; generally, it is problematic to functionalize the nanowires without changing their properties)
little control over inter-object spacing and/or on object orientation (especially by self-assembly through mechanical stretching, magnetic fields)
with most of the techniques hierachical organization of the nanowire pattern cannot be achieved; e.g. one-dimensional objects can only be aligned in one direction by surface interactions and mechanical stretching.
Some techniques are based on the incorporation of undesirable materials; e.g. for orientation by mechanical stretching the one-dimensional objects have to be mixed with polymers. Thus, it is difficult to incorporate the obtained aligned nanowires directly into electronic devices without separating off the polymers.

### SUMMARY OF THE INVENTION

In a first aspect, the invention provides a method of depositing nanowires on the surface of a substrate, comprising the steps of:
contacting defined regions of the substrate with at least one compound (C1) capable of binding to the surface of the substrate and of binding the nanowires to provide a pattern of binding sites on the surface of the substrate and/or contacting defined regions of the substrate with at least one compound (C2) capable of binding to the surface of the substrate and preventing the binding of nanowires to provide a pattern of non-binding sites on the surface of the substrate, and
contacting the surface of the substrate with a suspension of nanowires in a liquid medium to enable at least a portion of the applied nanowires to bind to at least a portion of the surface of the substrate covered with (C1) and/or not covered with (C2).

A first embodiment is a method, comprising the steps of:
(a) providing a stamp having a surface including a plurality of indentations formed therein defining an indentation pattern, said indentations being contiguous with a stamping surface and defining a stamping pattern,
(b) coating said stamping surface with at least one compound (C1),
(c) contacting at least a portion of the surface of a substrate with said stamping surface to allow deposition of said compound (C1) on the substrate,
(d) removing said stamping surface to provide a pattern of binding sites on the surface of the substrate,
(e) applying the suspension of nanowires to the surface of the substrate to enable at least a portion of the applied nanowires to bind to at least a portion of the binding sites on the surface of the substrate.

The free surface areas of the substrate obtained in step (d) can be left unmodified or be coated, e.g. with at least one compound (C2) capable of binding to the surface of the substrate and preventing the binding of nanowires.

A second embodiment is a method, comprising the steps of:
(a) providing a stamp having a surface including a plurality of indentations formed therein defining an indentation pattern, said indentations being contiguous with a stamping surface and defining a stamping pattern,
(b) coating said stamping surface with at least one compound (C2),
(c) contacting at least a portion of the surface of a substrate with said stamping surface to allow deposition of said compound (C2) on the substrate,
(d) removing said stamping surface to provide a pattern of sites on the surface of the substrate that prevent the binding of nanowires,
(e) applying the suspension of nanowires to the surface of the substrate to enable at least a portion of the applied nanowires to bind to at least a portion of the surface of the substrate not covered with (C2).

The free surface areas of the substrate obtained in step (d) can be left unmodified or be coated, e.g. with at least one compound (C1) capable of binding to the surface of the substrate and of binding the nanowires.

In a further aspect, the invention provides a method that additionally comprises the steps of:
contacting defined regions of the substrate with at least one compound (C3) capable of binding to the surface of the substrate and of binding at least one organic semiconducting compound (S) and/or contacting defined regions of the substrate with at least one compound (C4) capable of binding to the surface of the substrate and of preventing the binding of a compound (S),
applying a compound (S) to the surface of the substrate to enable at least a portion of the applied compound (S) to bind to at least a portion of the surface of the substrate covered with (C3) and/or not covered with (C4).

In a preferred embodiment, the compound (C3) is selected from compounds (C1) and (C2). In a further preferred embodiment, the compound (C4) is also selected from compounds (C1) and (C2).

In a further aspect the invention provides a method of manufacturing an electronic device comprising the step of depositing nanowires on a substrate, which in turn comprises the steps of:
contacting defined regions of the substrate with at least one compound (C1) capable of binding to the surface of the substrate and of binding the nanowires to provide a pattern of binding sites on the surface of the substrate and/or contacting defined regions of the substrate with at least one compound (C2) capable of binding to the surface of the substrate and preventing the binding of the nanowires to provide a pattern of non-binding sites on the surface of the substrate, and
contacting the surface of the substrate with a suspension of nanowires in a liquid medium to enable at least a portion of the applied nanowires to bind to at least a portion of the surface of the substrate covered with (C1) and/or not covered with (C2).

### BRIEF DESCRIPTION OF THE DRAWINGS

FIG. 1a and FIG. 1b show Ag nanowires (length 6 μm, diameter about 250 nm) coated with mercaptoundecanoic acid on an Au substrate patterned with hexdecane thiol (100×100 μm squares); patterns of metallic nanowires with random orientation can be employed as conducting electrodes; patterned semiconducting nanowire networks can be employed to fabricate FETs.

FIG. 2 shows Pd nanowires (length 6 μm, diameter 250 nm) coated with mercaptoundecanoic acid on an Au substrate patterned with hexdecane thiol (breadth of the patterned lines=0.834 μm; i.e the breadth of the lines is smaller than the length (longitudinal axes) of the nanowires; the nanowires are confined to and aligned with the hydrophilic pattern on the substrate;

FIG. 3 shows Pd nanowires coated with mercaptoundecanoic acid on a TiO₂ surface patterned with hexdecane thiol (breadth of the patterned lines=0.834 μm); an Au substrate was patterned with hexdecane thiol using microcontact printing; then the exposed Au surface was etched away by using hexdecane thiol as the mask, which results in alternating TiO₂ lines and hexdecane thiol lines; afterwards the nanowires were applied to the substrate;

FIG. 4a shows an Au substrate patterned with 20 μm with hexdecane thiol lines;

FIG. 4b shows the substrate of FIG. 4a after application of Ag nanowires coated with mercaptoundecanoic acid;

FIGS. 5a and 5b show Pd nanowires (length 6 μm, diameter 250 nm) coated with mercaptoundecanoic acid on an Au substrate patterned with hexadecane thiol (breadth of the lines=2 μm);

FIG. 6 shows an Au substrate (100 μm×100 μm squares of hexadecane thiol) patterned with mercaptoundecanoic acid coated Ag nanowires and copper phthalocyanine crystals;

FIG. 7 shows Pd/mercaptoundecanoic acid nanowires (length 6 μm, diameter 250 nm) on an Au substrate patterned with hexdecane thiol (breadth of the lines=2 μm); after the first patterning, hexdecane thiol was removed by heating; afterwards 2 μm hexdecane thiol lines were again microcontact printed onto the substrate in a direction perpendicular to the previous printing; 2 μm lined “electrodes” could be fabricated afterwards by etching away exposed Au regions;

FIG. 8a depicts a concept scheme of hierachical self-assembly;

FIG. 8b shows a pattern of nanowires obtained by the scheme of FIG. 8a on an Au substrate treated with hexdecane thiol (breadth of the lines=2 μm);

FIG. 9a shows a Pd/mercaptoundecanoic acid nanowires (length 6 μm, diameter 250 nm) on an Au substrate, patterned with hexadecane thiol and the sodium salt of 3-mercapto-1-propanesulfonic acid; the negatively charged nanowires could be patterned into negatively charged SO₃⁻Na⁺ regions of the substrate with 20 μm SO₃⁻Na⁺/20 μm hexadecane thiol pattern;

FIG. 9b shows an optical micrograph of Pd/mercaptoundecanoic acid nanowires (length 6 μm, diameter 250 nm) on an Au substrate, patterned with the sodium salt of 3-mercapto-1-propanesulfonic acid (20 μm squares) and hexadecane thiol; the negatively charged nanowires could be patterned into negatively charged SO₃⁻Na⁺ regions of the substrate; the inset shows the scanning electron microscope image of the nanowires patterned on the same substrate;

FIG. 10a depicts a nanowire suspension on a substrate being diluted with fluidic medium before being removed;

FIGS. 10b and 10c show that patterning of nanowires was not observed if the nanowire suspensions were diluted with large amounts of water before being removed;

FIG. 11a depicts a scheme for the production of an OFET from poly(3-hexylthiophene) (S and D correspond to the source and the drain, respectively);

FIG. 11b (according to the invention) and FIG. 11c show the transistor performance of an OFET obtained from poly(3-hexylthiophene);

### DETAILED DESCRIPTION OF PREFERRED EMBODIMENTS OF THE INVENTION

For the purpose of the present application, the term “nanowire” generally refers to any elongated conductive or semiconductive material that has longitudinal extension greater than its latitudinal extension. The diameter (cross-sectional dimension, breadth, width) is preferably not more than 1000 nm, more preferably not more than than 500 nm, especially not more than 300 nm. The longitudinal extension (length) is preferably at least 500 nm, more preferably at least 1000 nm (1 μm), especially at least 2 μm. Preferably the nanowire has an aspect ratio (length: width) greater than 5, preferably greater than 10, and especially greater than 20. The cross-section of the nanowire may have any arbitrary shape, including, but not limited to, circular, square, rectangular, elliptical and tubular. Regular and irregular shapes are included.

Various nanowires are suitable for use in the present invention. In principal, any electrically conductive or electrically semiconductive material capable of forming a nanowire may be employed. Suitable materials include metals, preferably metals of groups 8, 9, 10 or 11 of the periodic table, e.g. Pd, Au, Ag, Cu. Preferred electrically conductive materials have a resistivity lower than about 10⁻³, more preferably lower than about 10⁻⁴, and most preferably lower than about 10⁻⁶ or 10⁻⁷ ohm metres.

Suitable materials for the nanowires further include semiconductors, e.g. diamond (C), silicon (Si), germanium (Ge), silicon carbide (SiC), silicon germanide (SiGe), aluminium antimonide (AlSb), aluminium arsenide (AlAs), aluminium nitride (AlN), aluminium phosphide (AlP), boron nitride (BN), boron arsenide (BAs), gallium antimonide (GaSb), gallium arsenide (GaAs), gallium nitride (GaN), gallium phosphide (GaP), indium antimonide (InSb), indium arsenide (InAs), indium nitride (InN), indium phosphide (InP), aluminium gallium arsenide (AlGaAs, AlₓGa₁₋ₓAs), indium gallium arsenide (InGaAs, InₓGa₁₋ₓAs), aluminium indium antimonide (AlInSb), gallium arsenide nitride (GaAsN), gallium arsenide phosphide (GaAsP), aluminium gallium nitride (AlGaN), aluminium gallium phosphide (AlGaP), indium gallium nitride (InGaN), indium arsenide antimonide (InAsSb), indium gallium antimonide (InGaSb), aluminium gallium indium phosphide (AlGaInP, also InAlGaP, InGaAlP, AlInGaP), aluminium gallium arsenide phosphide (AlGaAsP), indium gallium arsenide phosphide (InGaAsP), aluminium indium arsenide phosphide (AlInAsP), aluminium gallium arsenide nitride (AlGaAsN), indium gallium arsenide nitride (InGaAsN), indium aluminium arsenide nitride (InAlAsN), gallium indium nitride arsenide antimonide (GaInNAsSb), cadmium selenide (CdSe), cadmium sulfide (CdS), cadmium telluride (CdTe), zinc oxide (ZnO), zinc selenide (ZnSe), zinc sulfide (ZnS), zinc telluride (ZnTe), cadmium zinc telluride (CdZnTe, CZT), mercury cadmium telluride (HgCdTe), mercury zinc telluride (HgZnTe), mercury zinc selenide (HgZnSe), cuprous chloride (CuCl), lead selenide (PbSe), lead sulfide (PbS), lead telluride (PbTe), tin sulfide (SnS), tin telluride (SnTe), lead tin telluride (PbSnTe), thallium tin telluride (Tl₂SnTe₅), thallium germanium telluride (Tl₂GeTe₅), bismuth telluride (Bi₂Te₃), cadmium phosphide (Cd₃P₂), cadmium arsenide (Cd₃As₂), cadmium antimonide (Cd₃Sb₂), zinc phosphide (Zn₃P₂), zinc arsenide (Zn₃As₂), zinc antimonide (Zn₃Sb₂),

Further, the semiconductor may comprise a dopant, selected from p-type dopants and n-type dopants. E.g. zinc, cadmium, or magnesium can be used to form p-type semiconductors and tellurium, sulfur, selenium, or germanium can be used as dopants to form n-type semiconductors.

Conventional methods used for the synthesis of nanowires include pulse laser vaporization and chemical vapor deposition. One technique for fabricating semiconducting nanowires involves oxide-assisted growth. This technique requires the use of an oxide of the particular metal or alloy that is to be grown into a wire as well as a laser to oblate the oxide (see, e.g., Shi et al. “Oxide Assisted Growth and Optical Characterization of Gallium-Arsenide Nanowires” 78, Applied Physics Letters, 3304 (2001) and U.S. Pat. No. 6,313,015). US patent application 2004/023471 describes the preparation of semiconducting crystalline nanowires by thermal evaporation. Metallic nanowires are commercially available from Nanoplex Technologies, Inc., Mountain View, Calif. Suitable synthetic methods are disclosed in the following documents: Science, 2001, 294, 137; J. Electranal. Chem. 2002, 522, 95-103.

For the purposes of the present application, the term “binding” is understood in a broad sense. This covers every kind of binding interaction between a compound (C1) and/or a compound (C2) and the surface of the substrate as well as every kind of binding interaction between a compound (C1) and a nanowire. The types of binding interaction include the formation of chemical bonds (covalent bonds), ionic bonds, coordinative interactions, van der Waals interactions (e.g. dipole dipole interactions), etc. and combinations thereof. In one preferred embodiment, at least one of the binding interactions between the compound (C1), the surface of the substrate and the crystalline compounds is an adhesive interaction.

Suitable compounds (C2) are compounds with a lower affinity to the nanowires than to the untreated substrate or, if present, (C1). If a substrate is only coated with at least one compound (C2), it is of critical importance that the strength of the binding interaction of (C2) and of the substrate with the nanowires differ to a sufficient degree so that the nanowires are essentially deposited on substrate areas not patterned with (C2). If a substrate is coated with at least one compound (C1) and at least one compound (C2), it is of critical importance that the strength of the binding interaction of (C1) and (C2) with the nanowires differ to a sufficient degree so that the nanowires are essentially deposited on substrate areas patterned with (C1). In a preferred embodiment the interaction between (C2) and the nanowires is a repulsive interaction. For the purpose of the present application, the term “repulsive interaction” is understood in a broad sense and covers every kind of interaction that prevents deposition of the nanowires on areas of the substrate patterned with compound (C2). Accordingly, the present invention provides a method for patterning the surface of a substrate with at least one type of nanowire using at least one self-assembly step. The method includes providing a substrate with a surface that has a preselected pattern of binding sites located thereon. The binding sites are capable of binding to the nanowires. In a further embodiment, at least part of the surface of the nanowires, employed in the process of the invention is also modified with at least one compound capable of binding to specific areas on the surface of the substrate.

Thus, the present invention allows assembly or controlled placement of nanoscopic wires on the surfaces of the substrates. In addition to patterning the surface of the substrate with compounds (C1) and/or (C2) and optionally modifying the surface of the nanowires, alignment of the nanowires can be supported by, inter alia.
the choice of suitable dimensions of the substrate pattern and the nanowires,
the method of application of the nanowire (patterning time, removal of unbound nanowires from the substrate, repeated patterning of the substrate with compounds (C1) and/or (C2) and application of nanowires, etc.)

Alignment of the nanowires leads to e.g. the spanning of the distance between contact electrodes located in or on the substrate. Thus, individual contact points may be arranged on the substrate and a binding site may be generated between such points (e.g. by positioning a compound (C1) between such points by microprinting) that will attract a single nanowire or a number of aligned nanowires to span the distance between the points, thereby forming an electronic pathway between the points. Thus, individual nanowires or a number of aligned nanowires may be assembled between individual pairs of electrical contacts. A hierarchical self-assembly of nanowires can be obtained by repeating the steps (i) contacting defined regions of the substrate with at least one compound (C1) and/or (C2) and (ii) contacting the surface of the substrate with a suspension of nanowires to enable at least a portion thereof to bind to at least a portion of the surface of the substrate covered with (C1) and/or not covered with (C2), once or a number of times. Thus, e.g. crossed-wire arrangements, including multiple crossings (a number of parallel wires in a first direction crossed by a number of parallel wires in a (e.g. essentially perpendicular) second direction can be formed.

The method according to the invention can be used to provide a wide variety of devices. Such devices may include electrical devices, optical devices, optoelectronic devices (e.g. semiconductor devices for communications and other applications such as light emitting diodes, electroabsorptive modulators and lasers), mechanical devices and combinations thereof. Functional devices assembled from nanowires according to the method of the present invention may be used to produce various IC architectures.

For example, nanowires of the invention may be assembled into nanoscale versions of conventional semiconductor devices, such as diodes, light-emitting diodes (LEDs), inverters, sensors, and bipolar transistors. These may include single, free-standing nanowires, crossed nanoscale wires, or combinations of single nanowires or aligned nanowires combined with other components. Metallic nanowires may be used for connection in these devices, as an interconnect between two devices, or between a device and an external circuit or system. Further, semiconducting nanowires having e.g. different dopants, doping levels, or combinations of dopants may be used to produce these devices. The nanowires may also have multiple regions, each of which may have different compositions. In a special embodiment, a single nanoscale wire may operate as a functional device or part of a functional device, e.g. a semiconductor. One aspect of the present invention includes the use of the method of the invention to fabricate an electronic device from adjacent n-type and/or p-type semiconducting components. This includes any device that can be made by the method of the invention that one of ordinary skill in the art would desirably make using semiconductors. Examples of such devices include, but are not limited to, field effect transistors (FETs), bipolar junction transistors (BJTs), tunnel diodes, modulation doped superlattices, complementary inverters, light-emitting devices, light-sensing devices, biological system imagers, biological and chemical detectors or sensors, thermal or temperature detectors, Josephine junctions, nanoscale light sources, photodetectors such as polarization-sensitive photodetectors, gates, inverters, AND, NAND, NOT, OR, TOR, and NOR gates, latches, flip-flops, registers, switches, clock circuitry, static or dynamic memory devices and arrays, state machines, gate arrays, and any other dynamic or sequential logic or other digital devices including programmable circuits.

Thus, the present invention provides a method which causes previously prepared and optionally surface-modified nanowires to assemble themselves into microelectronic devices by “self-assembly”. By preparing a preselected pattern of adhesion sites via microprinting, the method is able to produce a fine pattern of nanowires and, optionally, further devices on a substrate. Especially preferred further devices are field-effect transistors (FETs). FETs are transistors that rely on an electrical field to control the shape and hence the conductivity of a channel in a semiconductor material. FETs generally have four terminals, which are known as the gate, the drain, the source and the body/base. Special embodiments of FETs are metal oxide semiconductor field-effect transistors (MOSFETs) and organic field-effect transistors (OFETs).

A further aspect of the present invention relates to a substrate having an array of OFETs. Preferably, each OFET includes an isolated crystallite of an organic semiconductor, a gate structure, a conductive source and drain electrodes located at opposite ends of a channel portion of the crystallite. The crystallite is located on the substrate and is not connected to a crystallite of another transistor by a continuous pathway of crystallite material, i.e. the crystallites of different OFETs are isolated from each other. The gate structures are positioned to control the conductivities of the channel portions of the crystallites. Nanowires are used for connection.

A further aspect of the present invention relates to a method for the deposition of semiconducting nanowire networks on a substrate for transistor applications.

The main driving force behind the self-assembly of the nanowires on the substrate, such as the local binding interaction of molecules with each other and the surface of the substrate, is at an atomic scale. Using the method of the invention, there is no need to use fluidic alignment or microfluidic channels for the positioning of nanowires on a substrate. Further, there is no need to use an electric or magnetic field to apply the nanowires to the substrate.

The process according to the invention has the following advantages:
a) This method can be generally used for aligning one-dimensional objects of different materials irrespective of their size, surface properties, and morphologies. It is not necessary that the objects have special electronic or magnetic properties.
b) This method enables high throughput, as the key steps (stamping and drop-casting) are high throughput processes.
c) This method is simple and cost-effective (no complicated design is required and valuable nanowire suspensions can be reused).
d) Nanowire alignment can be realized (e.g. by choosing patterns with appropriate shapes and nanowires with appropriate dimensions).
e) Hierarchical organization can be realized (It is feasible to pattern the substrates and align nanowires many times. Thus, nanowires aligned in different directions can be obtained.).
f) Incorporation of fewer impurities (In most cases water can be used as the liquid medium. It is especially not necessary to employ further media, such as polymers, for the self-assembly of the nanowires.).
g) Environmentally friendly (no substances causing environmental pollution are used).

Any material that allows the patterning of its surface with at least one compound (C1) can be used as the substrate. Preferred substrates are selected from materials suitable for the production of semiconductor devices. Suitable substrates include, for example, metals (preferably metals of groups 8, 9, 10 or 11 of the periodic table, e.g. Au, Ag, Cu), oxidic materials (like glass, quartz, ceramics, SiO₂), semiconductors (e.g. doped Si, doped Ge), metal alloys (e.g. on the basis of Au, Ag, Cu, etc.), semiconductor alloys, polymers (e.g. polyvinylchloride, polyolefines, like polyethylene and polypropylene, polyesters, fluoropolymers, polyamides, polyurethanes, polyalkyl(meth)acrylates, polystyrene and mixtures and composites thereof), inorganic solids (e.g. ammonium chloride), and combinations thereof. The substrate can be a flexible or inflexible solid substrate with a curved or planar geometry, depending on the requirements of the desired application.

A typical substrate for semiconductor devices comprises a matrix (e.g. quartz or polymer matrix) and, optionally, a dielectric top layer (e.g. SiO₂). The substrate also generally includes electrodes, such as the drain and source electrodes of FETs, which are usually located on the substrate (e.g. deposited on the nonconductive surface of the dielectric top layer). The substrate also generally includes conductive gate electrodes of the FETs that are typically located below the dielectric top layer (i.e., the gate dielectric). Of course, the substrate can contain further components that are usually employed in semiconductor devices or ICs, such as insulators, resistive structures, capacitive structures, metal tracks, etc.

The compound (C1) usually comprises at least one functional group capable of interaction with the surface of the substrate and also at least one functional group capable of interaction with the nanowire materials. The functional groups capable of interaction with the surface of the substrate can be the same as the functional groups capable of interaction with the nanowire materials. Alternatively, the compound (C1) can comprise two different species of functional groups, one for the interaction with the substrate and the other for the interaction with the nanowires.

In the following, the term “hydrocarbon group” comprises alkyl groups, cycloalkyl groups, heterocycloalkyl groups, aryl groups, heteroaryl groups and combinations thereof.

In the following, the expression “alkyl” comprises straight-chain and branched alkyl groups. These groups are preferably straight-chain or branched C₁-C₂₀-alkyl groups, more preferably C₁-C₁₂-alkyl groups, particularly preferably C₁-C₈-alkyl groups and most preferably C₁-C₄-alkyl groups. Examples of alkyl groups are, in particular, methyl, ethyl, propyl, isopropyl, n-butyl, 2-butyl, sec-butyl, tert-butyl, n-pentyl, 2-pentyl, 2-methylbutyl, 3-methylbutyl, 1,2-dimethylpropyl, 1,1-dimethylpropyl, 2,2-dimethylpropyl, 1-ethylpropyl, n-hexyl, 2-hexyl, 2-methylpentyl, 3-methylpentyl, 4-methylpentyl, 1,2-dimethylbutyl, 1,3-dimethylbutyl, 2,3-dimethylbutyl, 1,1-dimethylbutyl, 2,2-dimethylbutyl, 3,3-dimethylbutyl, 1,1,2-trimethylpropyl, 1,2,2-trimethylpropyl, 1-ethylbutyl, 2-ethylbutyl, 1-ethyl-2-methylpropyl, n-heptyl, 2-heptyl, 3-heptyl, 2-ethylpentyl, 1-propylbutyl, n-octyl, 2-ethylhexyl, 2-propylheptyl, nonyl, decyl. Suitable longer-chain C₈-C₃₀-alkyl or C₈-C₃₀-alkenyl groups are straight-chain and branched alkyl or alkenyl groups. octyl(ene), nonyl(ene), decyl(ene), undecyl(ene), dodecyl(ene), tridecyl(ene), tetradecyl(ene), pentadecyl(ene), hexadecyl(ene), heptadecyl(ene), octadecyl(ene) and nonadecyl(ene) etc.

The expressions “alkyl” and “alkylene” also comprise substituted alkyl groups which can generally bear 1, 2, 3, 4 or 5 substituents, preferably 1, 2 or 3 substituents and particularly preferably 1 substituent, selected from among cycloalkyl, aryl, hetaryl, halogen, hydroxy, thiol, NE¹E², NE¹E²E³⁺, COOH, carboxylate, —SO₃H and sulfonate.

“Cycloalkyl” is preferably C₅-C₈-cycloalkyl, such as cyclopentyl, cyclohexyl, cycloheptyl or cyclooctyl.

For the purposes of the present invention, the term “Heterocycloalkyl” includes saturated, cycloaliphatic groups with in general 4 to 7, preferably 5 or 6, ring atoms in which 1 or 2 of the ring carbon atoms are replaced by heteroatoms chosen from the elements oxygen, nitrogen and sulfur and which may optionally be substituted. In the case of a substitution,these heterocycloaliphatic groups may carry 1, 2 or 3, preferably 1 or 2, particularly preferably 1, substituent chosen from alkyl, aryl, COOR^{a}, COO-M⁺ and NE¹E², preferably alkyl.

Examples of heterocycloaliphatic groups which may be mentioned are pyrrolidinyl, piperidinyl, 2,2,6,6-tetramethylpiperidinyl, imidazolidinyl, pyrazolidinyl, oxazolidinyl, morpholidinyl, thiazolidinyl, isothiazolidinyl, isoxazolidinyl, piperazinyl, tetrahydrothiophenyl, tetrahydrofuranyl, tetrahydropyranyl and dioxanyl.

“Aryl” includes unsubstituted and substituted aryl groups and is preferably phenyl, tolyl, xylyl, mesityl, naphthyl, fluorenyl, anthracenyl, phenanthrenyl, naphthacenyl and, in particular, phenyl, tolyl, xylyl or mesityl.

“Hetaryl” is preferably pyrrolyl, pyrazolyl, imidazolyl, indolyl, carbazolyl, pyridyl, quinolinyl, acridinyl, pyridazinyl, pyrimidinyl or pyrazinyl.

The groups NE¹E² are preferably N,N-dimethylamino, N,N-diethylamino, N,N-dipropylamino, N,N-diisopropylamino, N,N-di-n-butylamino, N,N-di-t-butylamino, N,N-dicyclohexylamino or N,N-diphenylamino.

Halogen is fluorine, chlorine, bromine or iodine.

In a first preferred embodiment, the compound (C1) is bound to the surface of the substrate and/or to the nanowires via covalent interactions. According to this embodiment, the compound (C1) comprises at least one functional group, capable of reaction with a complementary functional group of the substrate and/or the nanowires. In the context of the present invention, “complementary functional groups” mean a pair of functional groups which are able to react with one another under the formation of a covalent bond. Preferably, the complementary functional groups react with one another in a condensation or addition reaction.

Suitable functional groups for covalent interactions are preferably selected from hydroxyl, primary and secondary amino, thiol, carboxylic acid, carboxylic ester, carboxamide, carboxylic anhydride, sulfonic acid, sulfonic ester, isocyanate, blocked isocyanate, urethane, urea, ether, and epoxy groups.

Examples of pairs suitable for reaction are, on the one hand, compounds having active hydrogen atoms, selected from e.g. compounds containing alcohol, primary and secondary amine, and thiol groups, and, on the other hand, compounds having groups reactive therewith, selected from e.g. carboxylic acid, carboxylic ester, carboxamide, carboxylic anhydride, isocyanate, urethane, urea, alcohol, ether and epoxy groups. Further examples of suitable pairs are compounds containing epoxy groups, on the one hand, and carboxylic acid groups, on the other. It is generally not critical which functional group of the pair carries the compound (C1) and which the substrate or the nanowire material.

Table 1 exemplifies suitable pairs of complementary functional groups

TABLE 1
complementary functional groups

| | reactive group R | | | | | | |
|---|---|---|---|---|---|---|---|
| complementary | | (meth)acrylate/ | | | | | |
| group R′ | isocyanate | vinyl | —SH | —NH₂ | —OH | —CHO | epoxy |
| isocyanate | X* | | X | X | X | | |
| (meth)acrylate | | | X | X | X | | |
| vinyl | | | X | X | X | | |
| —SH | X | X | | | | X | X |
| —NH₂ | X | X | | | | X | X |
| —OH | X | X | | | | | X |
| —COOH | X | | | | | | |
| epoxy | | | X | X | X | | |
| —CHO | | | X | X | | | |

*in the presence of water

The resulting covalent bonds are preferably selected from ester bonds, amide bonds, sulfonamide bonds, imino bonds, amidino bonds, urethane bonds, urea bonds, thiourethane bonds, thiourea bonds, sulfide bonds, sulfonyl bonds, ether bonds and amino bonds.

Suitable functional groups are also radically polymerizable C═C double bonds, comprising, in addition to the aforementioned (meth)acrylate groups, also vinylether and vinylester groups.

In a second preferred embodiment the compound (C1) is bound to the surface of the substrate and/or to the nanowires via ionic interactions. According to this embodiment, the compound (C1) comprises at least one functional group capable of ionic interaction with the surface of the substrate and/or the nanowires.

In a third preferred embodiment the compound (C1) is bound to the surface of the substrate and/or to the nanowires via dipole interactions, e.g. van der Waals forces.

The interaction between (C1) and the substrate and/or between (C1) and the nanowire material is preferably an attractive hydrophilic-hydrophilic interaction or attractive hydrophobic-hydrophobic interaction. Hydrophilic-hydrophilic interaction and hydrophobic-hydrophobic interaction can comprise, among other things, the formation of ion pairs or hydrogen bonds and may involve further van der Waals forces.

Hydrophilicity or hydrophobicity is determined by affinity to water. Predominantly hydrophilic compounds or material surfaces have a high level of interaction with water and generally with other hydrophilic compounds or material surfaces, whereas predominantly hydrophobic compounds or materials are not wetted or only slightly wetted by water and aqueous liquids. A suitable measure for assessing the hydrophilic/hydrophobic properties of the surface of a substrate is the measurement of the contact angle of water on the respective surface. According to the general definition, a “hydrophobic surface” is a surface on which the contact angle of water is >90°. A “hydrophilic surface” is a surface on which the contact angle with water is <90°. Compounds or material surfaces modified with hydrophilic groups have a smaller contact angle than the unmodified compound or materials. Compounds or material surfaces modified with hydrophobic groups have a larger contact angle than the unmodified compounds or materials.

Suitable hydrophilic groups for the compounds (C1) (as well as (C2) and/or the nanowires) are those selected from ionogenic, ionic, and non-ionic hydrophilic groups. lonogenic or ionic groups are preferably carboxylic acid groups, sulfonic acid groups, nitrogen-containing groups (amines), carboxylate groups, sulfonate groups, and/or quaternized or protonated nitrogen-containing groups. Suitable non-ionic hydrophilic groups are e.g. polyalkylene oxide groups. Suitable hydrophobic groups for the compounds (C1) (as well as (C2) and/or the nanowires) are those selected from the aforementioned hydrocarbon groups. These are preferably alkyl, alkenyl, cycloalkyl, or aryl radicals, which can be optionally substituted, e.g. by 1, 2, 3, 4, 5 or more than 5 fluorine atoms.

Further suitable functional groups of the compounds (C1) are also ligand groups, capable of coordinating metal ions that can form additional coordinative bonds to the substrate and or the nanowires. Functional groups suitable as ligands are e.g. carboxylic groups, hydroxyl groups, amino groups, SH groups, oxime groups, aldehyde groups, keto groups and heterocyclic groups like pyridine, chinoline, imidazole or oxazole.

In order to modify the surface of the substrate with a plethora of functional groups it can be activated with acids or bases. Further, the surface of the substrate can be activated by oxidation, irradiation with electron beams or by plasma treatment. Further, substances comprising functional groups can be applied to the surface of the substrate via chemical vapor deposition (CVD).

Suitable functional groups for interaction with the substrate include:
silanes, phosphonic acids, carboxylic acids, and hydroxamic acids: Suitable compounds (C1) comprising a silane group are alkyltrichlorosilanes, such as n-(octadecyl)trichlorosilane (OTS); compounds with trialkoxysilane groups, e.g. trialkoxyaminoalkylsilanes like triethoxyaminopropylsilane and N[(3-triethoxysilyl)propyl]ethylendiamine; trialkoxyalkyl-3-glycidylethersilanes such as triethoxypropyl-3-glycidylethersilane; trialkoxyallylsilanes such as allyltrimethoxysilane; trialkoxy(isocyanatoalkyl)silanes; trialkoxysilyl(meth)acryloxyalkanes and trialkoxysilyl(meth)acrylamidoalkanes, such as 1-triethoxysilyl-3-acryloxypropan. (These groups are preferably employed to bind to metal oxide surfaces such as silicon dioxide, aluminium oxide, indium zinc oxide, indium tin oxide and nickel oxide.),
amines, phosphines and sulfur containing functional groups, especially thiols: (These groups are preferably employed to bind to metal substrates such as gold, silver, palladium, platinum and copper and to semiconductor surfaces such as silicon and gallium arsenide.)

In a preferred embodiment, the compound (C1) is selected from C₈-C₃₀-alkylthiols and is in particular hexadecane thiol. These compounds enable the application of nanowires to the surface of more hydrophobic substrates, such as Au as well as more hydrophilic substrates such as NH₄Cl.

In a further preferred embodiment the compound (C1) is selected from mercaptocarboxylic acids, mercaptosulfonic acids and the alkali metal or ammonium salts thereof. Examples of these compounds are mercaptoacetic acid, 3-mercaptopropionic acid, mercaptobutyric acid, mercaptooctanoic acid, mercaptoundecanoic acid, mercaptolauric acid, mercaptomyristic acid, mercaptopalmitic acid, mercaptostearic acid, mercaptoarachidic acid, mercaptosuccinic acid, 3-mercapto-1-propanesulfonic acid and the alkali metal or ammonium salts thereof, e.g. the sodium or potassium salts. These compounds are suitable for the hydrophilization of the surface of more hydrophobic substrates.

In a further preferred embodiment the compound (C1) is selected from alkyltrichlorosilanes, and is in particular n-(octadecyl)trichlorosilane (OTS). These compounds enable the application of nanowires to the surface of more hydrophobic substrates, such as SiO₂.

In addition to or as an alternative to deposition of said compound (C1) on the substrate, the substrate can be contacted with at least one compound (C2) capable of binding to the surface of the substrate as well as of interaction with the nanowire material to prevent deposition of nanowires on areas of the substrate not patterned with compound (C1).

According to a first embodiment, the compounds (C2) can be selected from the group of the aforementioned compounds (C1). Whether a particular compound acts as (C1) or as (C2) depends on the strength of its interaction with the nanowires. It is of critical importance that the strength of the binding interaction of (C1) and (C2) with the nanowires differs to a sufficient degree so that the nanowires are essentially deposited on substrate areas patterned with (C1).

According to a further embodiment, the compounds (C2) are selected from compounds with a repulsive hydrophilic-hydrophobic interaction with the nanowires. Suitable functional groups for repulsive interaction with certain nanowire materials are hydrocarbon groups and (partially or fully) halogenated hydrocarbon groups. The hydrocarbon or the halogenated hydrocarbon can be purely aliphatic or aromatic or can have a combination of aliphatic and aromatic groups. Halogenated hydrocarbons can bear one or more than one (e.g. 2,3,4,5 or more than 5) of the following halogen groups: fluorine, chlorine, bromine, iodine, or a combination thereof. Preferably, the partially or fully halogenated hydrocarbon is a partially or fully fluorinated hydrocarbon or a chlorofluorocarbon. The hydrocarbon or the halogenated hydrocarbon can optionally bear further substituents apart from halogen.

As mentioned above the invention provides in a first embodiment a method of patterning the surface of a substrate with at least one nanowire, comprising the step of depositing on the surface of the substrate at least one compound (C1) capable of binding to the surface of the substrate and of binding at least one nanowire material. According to this embodiment, preferably at least 90% by weight, more preferably at least 95% by weight, especially at least 99% by weight, of the nanowires bound to the surface of the substrate are bound to surface areas patterned with (C1) (and not to unpatterned areas of the substrate or, if present, areas of the substrate coated with (C2)).

The second embodiment is a method of patterning the surface of a substrate with at least one nanowire, comprising the step of depositing on the surface of the substrate at least one compound (C2) capable of binding to the surface of the substrate and of preventing the binding of a nanowire material. According to this embodiment, preferably at least 90% by weight, more preferably at least 95% by weight, especially at least 99% by weight, of the nanowires bound to the surface of the substrate are bound to surface areas not patterned with (C2) (i.e. to unpatterned areas of the substrate or, if present, areas of the substrate coated with (C1)).

In a preferred embodiment of the process according to the invention, nanowires are employed that bear on at least a part of their surface at least one compound (C1) and/or at least one compound (C2). For modification of their surface, nanowires can be brought into contact with at least one compound (C1) and/or at least one compound (C2) by known methods. Preferably, the nanowires are admixed with a solution of the compound(s) (C1) and/or (C2) in a liquid substance. Additionally, a binder may be employed, which essentially does not affect the electric properties of the nanowires. Suitable liquid substances are selected from inorganic and organic liquids and mixtures thereof. These include water, nonaqueous inorganic solvents, organic solvents such as monohydric alcohols (e.g. methanol, ethanol, n-propanol, isopropanol, butanols, pentanols, cyclohexanol), polyols (e.g. ethylene glycol, glycerol), ethers and glycol ethers (e.g. diethyl ether, dibutyl ether, anisole, dioxane, tetrahydrofuran, mono-, di-, tri-, polyalkylene glycol ethers), ketones (e.g. acetone, butanone, cyclohexanone), esters (e.g. ethyl acetate, glycol esters), halohydrocarbons (e.g. dichloromethane, chloroform, tetrachloromethane, dichloroethane), hydrocarbons (e.g. benzene, petroleum ether, ligroin, pentane, hexane, heptane, cyclohexane, methylcyclohexane, decalin, aromatics such as benzene, toluene, xylene) and mixtures of the aforementioned solvents. The liquid substance is preferably selected from water, water-miscible organic compounds and mixtures thereof. It is possible to carry out the process by contacting a nanowire with the solution of (C1) and/or (C2) by customary processes such as spraying, dipping, etc. A further measure which leads to the formation of coated nanowires is the preparation of a seed sol from components (C1) and/or (C2), and contacting the nanowires with the seed sol (sol-gel-process). Such a sol can be produced by known techniques. A further measure which can be employed according to the present invention is the destabilization of a mixture of dissolved components (C1) and/or (C2), e.g. by removing part of the solvent, by cooling a supersaturated solution, etc. In the process of the present invention, it has been found to be advantageous to ensure sufficient circulation of the reaction solution or the reaction mixture, e.g. by pumping or stirring, during deposition of the compounds (C1) and/or (C2) on the nanowires.

The method of the invention comprises the step of contacting the surface of the substrate with a suspension of nanowires in a liquid medium to enable at least a portion of the applied nanowires to bind to at least a portion of the surface of the substrate.

Preferably, the nanowire materials (including, if present, their surface layer) have a solubility in the liquid medium of not more than 10 g/l, more preferably of not more than 5 g/l, especially of not more than 1 g/l at 25° C./1013 mbar.

The liquid medium is preferably selected from water and mixtures of water and at least one water-miscible organic solvent. Mixtures of water and at least one water water-miscible organic solvent preferably contain not more than 20% by weight of organic solvents. Suitable water-miscible organic solvents are C₃-C₄-ketones such as acetone und methylethylketone, cyclic ethers such as dioxane and tetrahydrofurane, C₁-C₄-alkanoles such as methanol, ethanol, n-propanol, isopropanol, n-butanol, tert.-butanol, polyoles and mono-und dimethylether thereof, such as glycole, propane diol, ethyleneglycolmonomethylether, diethyleneglycol, diethyleneglycolmonomethylether, diethyleneglycoldimethylether, glycerol, C₂-C₃-nitriles, like acetonitrile und propionitrile, dimethylsulfoxide, dimethylformamide, formamide, acetamide, dimethylacetamide, butyrolacton, 2-pyrrolidone und N-methylpyrrolidone. Preferred as the liquid medium are water and mixtures of water and at least one C₁-C₄-alkanol.

The suspension of the nanowires used in the process of the invention may comprise at least one surfactant to stabilize the nanowire particles. The surfactant is preferably a nonionic surfactant. However, ionic surfactants, e.g. anionic emulsifiers, anionic protective colloids, cationic emulsifiers, cationic protective colloids and zwitterionic (betainic) emulsifiers are also suitable. In a preferred embodiment, no surfactants are employed.

The solids content of the suspension is generally in the range of 0.001 to 20% by weight and in particular in the range of 0.1 to 10% by weight.

A suspension of nanowires may be prepared by dispersing nanowires in a liquid medium and and sonicating for a sufficient period of time to obtain a stable suspension.

For the application of the nanowire suspension to the substrate, known wet application techniques that lead to the formation of a liquid layer of the suspension on the substrate can be used. Such methods comprise pipetting, casting or different coating techniques, e.g. air blade coating, knife coating, air knife coating, impregnation, roll coating, gravure coating, kiss coating, spray coating, spin coating or printing processes. In the case of pipetting, a suspension of the nanowires is added dropwise to the patterned substrate. In the case of casting, the patterned substrate is flooded with a suspension of the nanowires. The layer thickness of the applied nanowire suspension is preferably from about 0.05 to 50 mm, in particular from 0.1 to 10 mm.

As a rule, the nanowires are oriented spontaneously during the application process. Preferably, the method of the invention (in particular step e) comprises applying the suspension of nanowires and contacting it with the surface of the substrate for a period of time sufficient to enable at least a portion of the applied nanowires to bind to at least a portion of the surface, and removing the suspension of unbound nanowires from the substrate. The time of contact is preferably within a range of from 30 seconds to 12 hours, more preferably of from 1 minute to 6 hours, and in particular of from 2 minutes to 2 hours. The liquid amount of the suspension can be reduced during application, e.g. by vaporization of a part of the liquid medium, typically by spontaneous evaporation. The rate of evaporation can be accelerated by means of one or more methods known in the art such as heat, reduced pressure, ventilation, and the like. The reduction of the liquid phase is stopped at least shortly before complete drying. Preferably not more than 50%, more preferably not more than 70%, especially not more than 90% of the liquid amount of the applied suspension is removed while the suspension is in contact with the substrate. Preferably, the suspension (comprising unbound nanowires) is removed before the liquid phase of the suspension is completely vaporized. Preferably, the suspension of unbound nanowires is removed from the substrate without dilution with a liquid medium. The suspension of unbound nanowires is preferably drawn off from the substrate by suction, e.g. with a pipette.

To obtain a high degree of aligning of the nanowires, preferably a pattern comprising linear binding sites is provided on the surface of the substrate, wherein the breadth of the lines is less than the length (longitudinal axes) of the nanowires. Preferably the ratio length: breadth is greater than 1.1, preferably greater than 2, and especially greater than 5.

In a preferred embodiment of the invention, the steps of:
contacting defined regions of the substrate with at least one compound (C1) to provide a pattern of binding sites on the surface of the substrate and/or contacting defined regions of the substrate with at least one compound (C2) to provide a pattern of non-binding sites on the surface of the substrate, and
contacting the surface of the substrate with a suspension of nanowires in a liquid medium to enable at least a portion of the applied nanowires to bind to at least a portion of the surface of the substrate covered with (C1) and/or not covered with (C2),

are repeated once or a number of times.

Preferably, after each repetition the compounds (C1) with no nanowires bound thereto and/or the compounds (C2) are removed from the substrate. Removal can be effected by treating the surface of the substrate with a suitable scrub liquid. Further, some of the compounds (C1) and/or (C2) can be removed by heat

In a further aspect, the invention provides a method of patterning the surface of a substrate with at least one further compound other than nanowires.

Preferably, the further compounds are selected from among crystalline compounds. A wide variety of crystalline compounds are suitable for use in the present invention. In principal, any electrically conductive, electrically nonconductive or electrically semiconductive material forming a solid crystalline phase at room temperature may be employed. Preferably, crystallites of at least one organic semi-conducting compound (S) are used as the crystalline compound.

Accordingly, the present invention provides a method for patterning the surface of a substrate with at least one nanowire material and at least one organic semiconducting compound using at least one self-assembly step. The method includes providing a substrate with a surface that has a preselected pattern of binding sites located thereon, wherein at least a part of the binding sites are capable of binding to crystallites of the semiconductor compound (S).

Advantageously, in the method of the invention a suspension of solid semiconductor particles in a liquid medium can be used for the application of the crystallites of the organic semiconductor (S) to the surface of the substrate. The organic semiconductor (S) can be applied previously to, simultaneously with or subsequently to the application of the nanowires. Of course, the application of nanowires and the application of semiconducting compounds can be repeated once or a number of times in any order whatsoever.

A further aspect of the present invention relates to a substrate having an array of OFETs. Each OFET includes an isolated crystallite of an organic semiconductor, a gate structure, a conductive source and drain electrodes located at opposite ends of a channel portion of the crystallite. The crystallite is located on the substrate and is not connected to a crystallite of another transistor by a continuous pathway of crystallite material, i.e. the crystallites of different OFETs are isolated from each other. The gate structures are positioned to control the conductivities of the channel portions of the crystallites.

Useful organic semiconductor compounds (S) are in principle those known to the person skilled in the art. These include acenes such as anthracene, tetracene, pentacene, and substituted acenes. A preferred acene is rubrene (5,6,11,12-tetraphenyinaphthacene). Substituted acene compounds useful as organic semiconductors in the present invention preferably comprise at least one substituent selected from the group consisting of electron-donating substituents (for example, alkyl, alkoxy, ester, carboxylate or thioalkoxy), electron withdrawing substituents (for example halogen, nitro or cyano) and combinations thereof. Useful substituted pentacenes are e.g. 2,9-dialkylpentacenes and 2,10-dialkylpentacenes, wherein the alkyl group has from 1 to 12 carbons, 2,10-dialkoxypentacenes, and 1,4,8,11-tetraalkoxypentacenes. Suitable substituted pentacenes are described in U.S. Published Appln. No. 2003/0100779, and U.S. Pat. No. 6,864,396. Examples of further useful organic semiconductors include perylenes, fullerenes, phthalocyanines, oligothiophenes, and substituted derivatives thereof. Suitable oligothiophenes are quaterthiophene, quinquethiophene, sexithiophene, α,ω-di(C₁-C₈)-alkyloligothiophenes, such as α,ω-dihexylquaterthiophene, α,ω-dihexylquinquethiophene and α,ω-dihexylsexithiophene, poly(alkylthiophenes) such as poly(3-hexylthiophene), bis(dithienothiophene), anthradithiophene and dialkylanthradithiophenes such as dihexylanthradithiophene, phenylene-thiophene (P-T) oligomers and derivatives thereof, especially α,ω-alkyl substituted phenylene-thiophene oligomers such as tert. butyl-P-T-T-P-tert. butyl oligomer. Examples of further useful organic semiconductors include polyacetylene, polythienylenevinylene, C60. Especially preferred are copper(II) phthalocyanine and rubrene.

Preferably, the method of the invention additionally comprises the steps of:
contacting defined regions of the substrate with at least one compound (C3) capable of binding to the surface of the substrate and of binding at least one organic semiconducting compound (S) and/or contacting defined regions of the substrate with at least one compound (C4) capable of binding to the surface of the substrate and preventing the binding of a compound (S),
applying a compound (S) to the surface of the substrate to enable at least a portion of the applied compound (S) to bind to at least a portion of the surface of the substrate covered with (C3) and/or not covered with (C4).

For binding interaction with (C3) and/or repulsive interaction with (C4) the semiconductors (S) can be subjected to a reaction to introduce functional groups capable of such an interaction. Suitable functional groups for covalent, ionic bonds, van der Waals, coordinative and other interactions are the aforementioned groups of component (C2). These groups can be introduced into the compounds (S) by e.g. reaction with functional groups of (S) that are capable of a condensation reaction or addition reaction and at least one compound selected from compounds that bear at least one functional group complementary to those groups of (S), wherein the compounds also bear at least one functional group capable of interacting with (C3) and/or (C4). In many cases it is not necessary to subject the semiconductors (S) to a functionalization, as compounds (C3) and, optionally, (C4) capable of interacting with the surface of the substrate and (S) are readily available. Thus, e.g. the aforementioned C₈-C₃₀-alkylthiols (C3) and, in particular, hexadecane thiol, are capable of attracting compounds (S) bearing hydrocarbon groups, e.g. aromatic rings or alkyl chains.

Preferably, the compound (C3) is selected from the group consisting of compounds (C1) and (C2). Especially, compounds (C3) correspond to compounds (C1).

Preferably, the compound (C4) is selected from the group consisting of compounds (C1) and (C2). Especially, compounds (C4) correspond to compounds (C2)

Preferably, the organic semiconductor compound (S) is employed in the form of crystallites. For the purpose of the invention, the term “crystallite” refers to small single crystals with maximum dimensions of 5 millimeters. Exemplary crystallites have maximum dimensions of 1 mm or less and preferably have smaller dimensions (frequently less than 500 μm, in particular less than 200 μm, for example in the range of 0.01 to 150 μm, preferably in the range of 0.05 to 100 μm), so that such crystallites can form fine patterns on the substrate. Here, an individual crystallite has a single crystalline domain, but the domains may include one or more cracks, provided that the cracks do not separate the crystallite into more than one crystalline domain. The stated particle sizes and the christallographic properties of the crystallites can be determined by direct X-ray analysis.

The particles of the semiconductor compound (S) may be of regular or irregular shape. For example, the particles can be present in spherical or virtually spherical form or in the form of needles.

Preferably, the organic semiconductor (S) is employed in the form of particles with a length/width ratio (L/W) of at least 1.05, more preferably of at least 1.5, especially of at least 3.

In an organic field effect transistor (OFET), a channel made of a single organic semiconductor crystal will typically have greater mobility than a channel made of a polycrystalline organic semiconductor. The high mobility results from the fact that the single crystal channel does not have grain boundaries. Grain boundaries lower the conductivities and mobilities of OFET channels made of polycrystalline organic semiconductor films.

Organic semiconductor crystallites, e.g. with diameters of about 1 to 10 microns or more, are readily available. Such organic semiconductor crystallites can be fabricated by methods described by R. A. Laudise et al in “Physical vapor growth of organic semiconductors” Journal of Crystal Growth 187 (1998), pages 449-454, and in “Physical vapor growth of centimeter-sized crystals of α-hexathiophene” Journal of Crystal Growth 182 (1997), pages 416-427. Both of these articles by Laudise et al are incorporated herein in their entirety by reference. The methods described by Laudise et al include passing an inert gas over an organic semiconductor substrate that is maintained at a temperature high enough that the organic semiconductor evaporates. The methods described by Laudise et al also include cooling down the gas saturated with organic semiconductor to cause an organic semiconductor crystallite to condense spontaneously. Such organic semiconductor crystallites are also commercially available. For example, BASF Corporation of 3000 Continental Drive-North, Mount Olive, N.J. 07828-1234, sells pigment crystallites that are organic semiconductors. One such crystallite is formed of copper phthalocyanine. The ready availability of organic semiconductor crystallites enables the construction of OFETs with high quality channels.

Preferably, a suspension of solid semiconductor particles in a liquid medium is used for applying a plurality of crystallites of the organic semiconductor compound (S) to the surface of the substrate.

Preferably, the semiconductor compound (S) has a solubility in the liquid medium of not more than 10 g/l, more preferably of not more than 5 g/l, especially of not more than 1 g/l at 25° C./1013 mbar.

The liquid medium is preferably selected from water and mixtures of water and at least one water-miscible organic solvent. Suitable liquid media are those mentioned above for the preparation of the nanowire suspension. The suspension of the semiconductor particles may comprise at least one surfactant to stabilize the semiconductor particles. Suitable surfactants are those mentioned above. In a preferred embodiment, no surfactants are employed. The solids content of the suspension of the semiconducting compound is generally in the range of 0.001 to 20% by weight and in particular in the range of 0.1 to 10% by weight. For the application of the crystallites of the organic semiconductor compound to the substrate, solution-based techniques such as pipetting, spin- or immersion-coating, i.e. dip-coating, can be used. In the case of pipetting, a suspension of the semiconductor crystallites is added dropwise to the patterned substrate. In the case of spin-coating, the patterned substrate is flooded with a suspension of the semiconductor crystallites and then spun to bring the substrate in intimate contact with the suspension. In the case of immersion-coating (dip-coating), the patterned substrate is immersed in a suspension containing the semiconductor crystallites, preferably under agitation of the suspension, and then withdrawn from the suspension. In all of these cases, the liquid medium is preferably removed from the substrate after the application by rinsing with a solvent. Preferably, the solvent corresponds to the liquid medium of the suspension used for the application of the crystallites. Afterwards, the solvent is removed, typically by spontaneous evaporation. The rate of evaporation can be accelerated by means of one or more methods known in the art such as heat, reduced pressure, ventilation, and the like.

In step a) of the process according to the invention, a stamp, having a surface including a plurality of indentations defining an indentation pattern formed therein, said indentations being contiguous with a stamping surface and defining a stamping pattern, is provided.

Stamps useful in the present invention are known in the art and are commercially available. Generally, these stamps can be produced by casting a polymeric material onto a mold having the desired pattern. The particular material chosen for formation of the stamp is not critical to the present invention, but should satisfy certain physical characteristics. In a preferred embodiment, the stamp is elastomeric. Polymeric materials suitable for use in fabrication of the stamp may have linear or branched backbones, and may be crosslinked or noncrosslinked, depending upon the particular polymer and the degree of formability desired of the stamp. A variety of elastomeric polymeric materials are suitable for such fabrication, especially polymers of the general classes of silicone polymers, epoxy polymers, and acrylate polymers. Examples of silicone elastomers suitable for use as stamps include those formed from precursors including the chlorosilanes such as methylchlorosilanes, ethylchlorosilanes, phenylchlorosilanes, and the like. A particularly preferred silicone elastomer is polydimethylsiloxane (PDMS). Exemplary silicone polymers include those sold under the trademark RTV by GE Advanced Materials and under the trademark Sylgard by the Dow Chemical Company, Midland, Mich., and particularly Sylgard 182, Sylgard 184, and Sylgard 186.

The stamp includes a stamping surface having a variety of features defined thereon by indentations. The form and dimensions of the indentations depend on the nature of the electronic devices to be formed on the substrate (e.g. molecular-sized transistors, connecting wires, etc.). Accordingly, the stamping surface may include features having a variety of lateral dimensions. Different patterns on the substrate can be obtained by the process of the invention. The elevations of the stamp defining the stamping pattern can have the same or different forms. Preferably the indentations are uniform and are e.g. in the form of a polygon, having 3, 4, 5, 6, 7, 8, 9, 10, 11 or 12 corners. Preferably, the indentations are rectangular, ellipsoidal or circular. Each indentation can have a minimum dimension of at least 50 nm, preferably at least 100 nm, more preferably at least 500 nm. Each indentation can have a maximum dimension of up to 5 mm, preferably of up to 1 mm, more preferably of up to 500 μm. Typical indentations are in the form of 10 μm-100 μm squares, 5-100 μm lines, and 10-100 μm dots. The distance between two adjacent indentations is preferably at least 50 nm, more preferably at least 100 nm, especially at least 500 nm.

A suitable method for forming the stamp is a photolytic method. For example, a mask may be positioned between the surface of the stamp and a source of irradiation, and the surface is irradiated through the mask for a predetermined period of time. Portions of the surface may be degraded by such irradiation, forming indentations in the surface upon removal of such degraded portions. According to this method, a variety of patterns may be very conveniently formed in a stamp according to a variety of available masks. In addition, the photolytic method may be used in combination with the above-described methods involving hardening a hardenable fluid on a mold surface. For example, a hardenable fluid may be contacted with a mold surface and allowed to harden to form the stamp having a predetermined stamping surface. In addition, the predetermined stamping surface may be irradiated through a mask to create additional features in the stamping surface. According to this method, a photoresist may be used as the stamp material itself. Particular types of polymers that may be patterned using the above-described photolytic method, preferred wavelengths for photopatterning, and lengths of time of photolysis are known in the art.

The surface of the mold serving as the master for the stamp may comprise any morphological features that may desirably serve as a template for the formation of the stamp for the patterning of a semiconductor on the surface of a substrate. For example, a microelectronic device such as an IC may serve as a template. The mold surface may be formed according to a variety of ways. According to one, the mold surface is micromachined from a material such as metal. According to another, the mold surface is formed lithographically by providing a substrate, depositing a film of material onto the substrate, coating an exposed surface of the material with resist, irradiating the resist according to a predetermined pattern, removing irradiated portions of the resist from the material surface, contacting the material surface with a reactant selected to react chemically therewith and selected to be chemically inert with respect to the resist such that portions of the material according to the predetermined pattern are degraded, removing the degraded portions, and removing the resist to uncover portions of the material formed according to the predetermined pattern to form the mold surface. According to another method for forming the mold surface, a substrate may be provided, and coated with resist. Subsequently, portions of the resist may be irradiated according to a particular predetermined pattern. Irradiated portions of the resist may then be removed from the substrate to expose portions of the substrate surface according to the predetermined pattern, and the substrate may be contacted with a plating reagent such that exposed portions according to the predetermined pattern are plated. Then, the resist may be removed to uncover portions of the exposed substrate according to the predetermined pattern bordered by plated portions of the substrate to form the mold surface.

In step b) of the process according to the invention, the stamping surface is coated with at least one compound (C1) or (C2) (i.e. the stamped being “inked” with at least one compound C1 or C2). The stamp may be inked with a solution comprising the compounds (C1) or (C2) that will be adsorbed to the stamp. Accordingly, the inking may be accomplished by e.g.: contacting the stamp with a material (i. e., paper, sponge) moistened with the ink, pouring the ink directly onto the stamp, applying the ink to the stamp with an appropriate application device (e. g. a cotton swab, brush, sprayer, syringe, etc.), or dipping the stamp surface into a solution comprising (C1) or (C2). The compound may be allowed to dry on the stamp or may be blown dry.

In step c) of the process according to the invention, at least a portion of the surface of the substrate is contacted with the stamping surface to allow deposition of the compound (C1) or (C2) on the substrate.

The inked stamp is then placed into contact with the functionalized polymer surface for a length of time sufficient for the compound (C1) or (C2) to be transferred to the surface of the substrate. The period of time required for the stamping process will of course vary with the compounds (C1) and (C2), the material of the stamp and the substrate being used. A person skilled in the art will be able to determine a suitable amount of time. For example, contacting the stamping surface with the surface of the substrate for a period of time in the range of approximately 1 second to 5 minutes (e.g. 5 to 60 seconds) is generally adequate to effect sufficient transfer, but contact may be maintained for longer or shorter periods of time if necessary or appropriate.

In step d) of the process according to the invention, the stamping surface is removed to provide a pattern of binding sites on the surface of the substrate. These binding sites are capable of binding nanowires and/or crystallites of the organic semiconductor compound (S) by the aforementioned mechanisms.

In one embodiment of the present invention, the substrate may be stamped more than once, e.g. to produce different types of binding sites on the surface of the substrate. The presence of different species of binding sites can be useful for the construction of complex circuits. For example, the different species of binding sites can be modified with different compounds (C1); thus, nanowires and further components, e.g. semiconductors (S), or different nanowires or different semiconductors (S) can be bound to the substrate.

The substrate with the pattern of binding sites thereon, obtained in step d) by the method according to the first embodiment of the invention, can optionally be contacted with at least one compound (C2) as defined above. The compounds (C2) are usually employed to cover those areas of the substrate that bear no binding sites. As the compounds (C2) usually show a repulsive interaction with the binding sites formed by compounds (C1) and are not capable of replacing or covering the binding sites, they can be applied by contacting the surface of the substrate with a solution of at least one compound (C2) in a suitable solvent. After a span of time sufficient to bind (C2) to the surface of the substrate, the solution is preferably removed from the substrate by rinsing with a solvent. Of course, defined areas of the substrate can also be patterned with at least one compound (C2) using the pattern technique according to the invention.

The substrate with a pattern of sites on the surface that prevent binding of a nanowire and/or a crystalline compound, obtained in step d) by the method according to the second embodiment of the invention, can optionally be contacted with at least one compound (C1) to allow deposition of the nanowires and/or crystalline compound on areas of the substrate not patterned with compound (C2). As mentioned above, the compounds (C2) usually show a repulsive interaction with the compounds (C1) and the compounds (C1) are usually not capable of replacing or covering sites already covered with (C2). Therefore, (C1) can usually be applied to those substrates by contacting the surface of the substrate with a solution of at least one compound (C1) in a suitable solvent. After a span of time sufficient to bind (C1) to the surface of the substrate, the solution is preferably removed from the substrate by rinsing with a solvent. Of course, defined areas of the substrate can also be patterned with at least one compound (C1) by using the pattern technique for application of (C2).

The invention will now be described in more detail on the basis of the accompanying figures and the following examples.

### EXAMPLES

### Examples

General Procedure:

Nanowires functionalized on their surface with mercaptoundecanoic acid could be dispersed in water by slight sonication. Substrates with hydrophilic/hydrophobic regions could be patterned through the following microcontact printing process: A PDMS stamp with different patterns was made by pouring PDMS precursors and cross-linkers (weight ratio around 10:1, Silguard 184 from Dow Chemical) against Si master and curing them at 65° C. for 8 hours. The obtained PDMS stamp was then inked with a substance (C1) by swiping several mM solutions (e. g. thiol or silane) with a Q-tip and then drying by air-flow. The substrate surface could be patterned by contacting with a PDMS stamp for around 20 seconds, and then rinsing with solvent and drying in air. The regions that were not contacted with the stamp could be optionally backfilled by soaking in 1 mM solutions of different molecules (C2) for around 30 min, followed by rinsing with solvent and drying in air. Nanowires and crystals of semiconductor compounds (S) could be patterned onto substrates from crystal suspensions through drop-casting. The suspensions of unbound compounds were removed by pipetting.

### Example 1

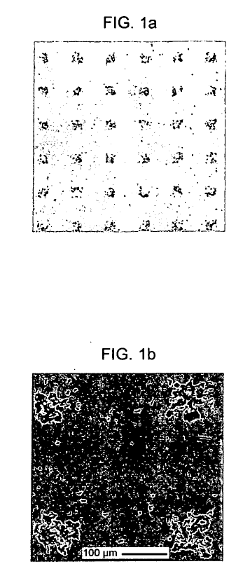

Ag nanowires coated with mercaptoundecanoic acid were applied to an Au substrate (100 μm×100 μm squares) patterned with hexadecane thiol from a nanowire suspension having a nanowire concentration of about 10⁶-10⁷ nanowires per ml using water as the suspension medium. The nanowires were applied by pipetting and the patterning time was about 10 min. The resulting pattern is shown in FIGS. 1a and 1b.

### Example 2

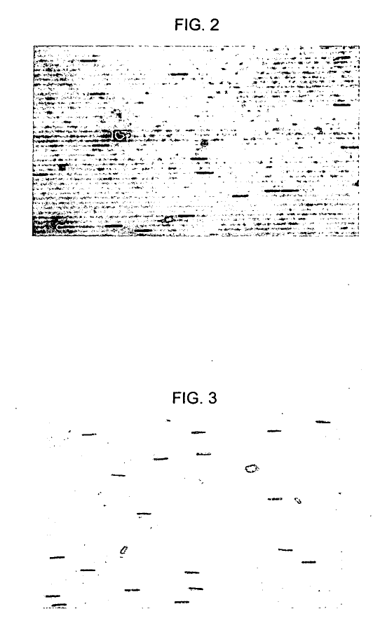

Pd nanowires coated with mercaptoundecanoic acid were applied to an Au substrate with 0.834 μm stripes of unmodified Au and 0.834 μm stripes patterned with hexadecane thiol (nanowire concentration: about 10⁶-10⁷ nanowires per ml; solvent: water; patterning time: about 10 min).The resulting pattern is shown in FIG. 2.

### Example 3

Pd nanowires coated with mercaptoundecanoic acid were applied to an Au substrate with 0.834 μm stripes of TiO₂ and 0.834 μm stripes patterned with hexadecane thiol (nanowire concentration: about 10⁶-10⁷ nanowires per ml; solvent: water; patterning time: about 10 min). The resulting pattern is shown in FIG. 3.

### Example 4

Ag nanowires coated with mercaptoundecanoic acid were applied to an Au substrate with 20 μm stripes of unmodified Au and 20 μm stripes patterned with hexadecane thiol.

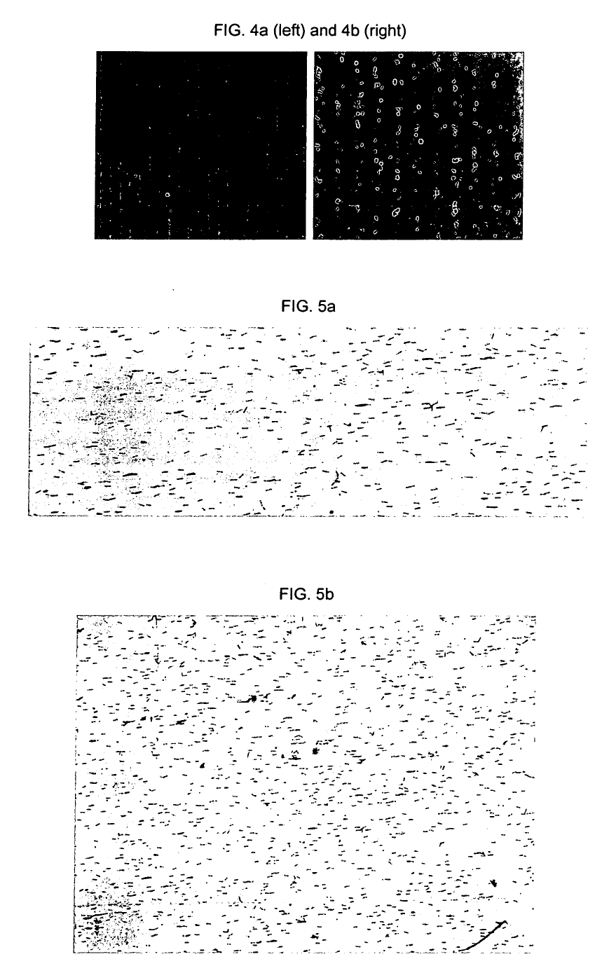

FIG. 4a shows the Au substrate patterned with with hexdecane thiol lines;

FIG. 4b shows the substrate of FIG. 4a after application of the Ag nanowires;

### Example 5

Pd nanowires coated with mercaptoundecanoic acid were applied to an Au substrate with 2 μm stripes of unmodified Au and 2 μm stripes patterned with hexadecane thiol. The resulting pattern is shown in FIGS. 5a and 5b.

### Example 6

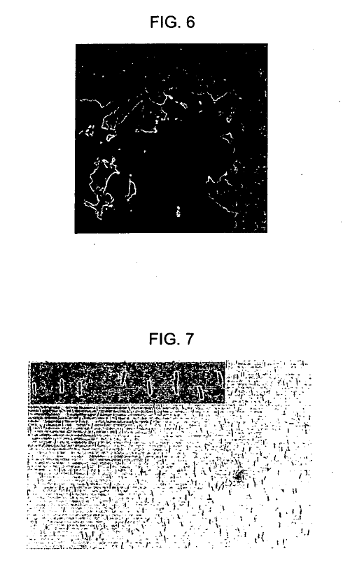

Ag nanowires coated with mercaptoundecanoic acid and CuPc crystals were applied to an Au substrate (100 μm×100 μm squares) patterned with hexdecane thiol. The resulting pattern is shown in FIG. 6.

### Example 7

Pd nanowires coated with mercaptoundecanoic acid were applied to an Au substrate with 2 μm stripes of unmodified Au and 2 μm stripes patterned with hexadecane thiol. The hexadecane thiol was removed by heating. Afterwards 2 μm hexdecane thiol lines were again microcontact printed onto the substrate in a direction perpendicular to the previous printing and Pd nanowires coated with mercaptoundecanoic acid were applied. The resulting pattern is shown in FIG. 7.

### Example 8

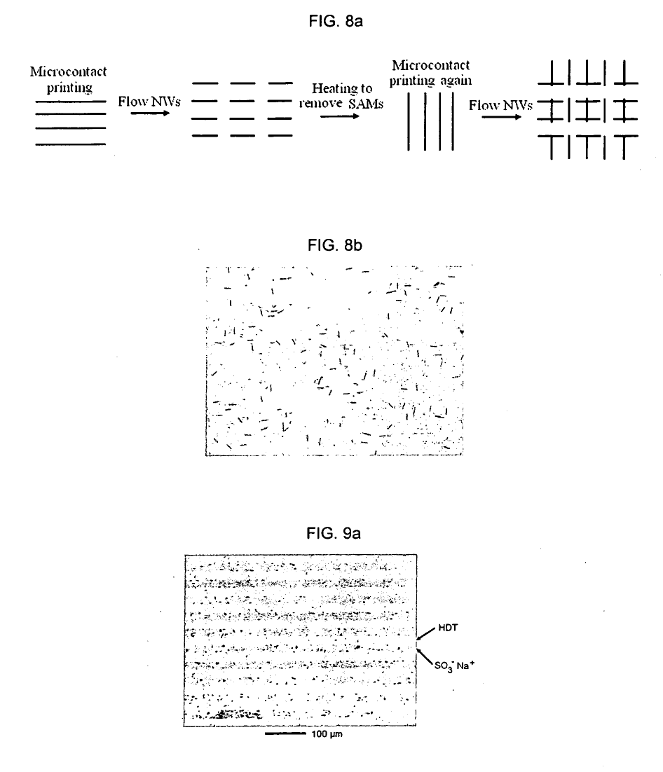

FIG. 8a depicts a concept scheme of hierachical self-assembly and FIG. 8b shows a pattern of nanowires obtained by this scheme on an Au substrate treated with hexdecane thiol (breadth of the lines=2 μm).

### Example 9

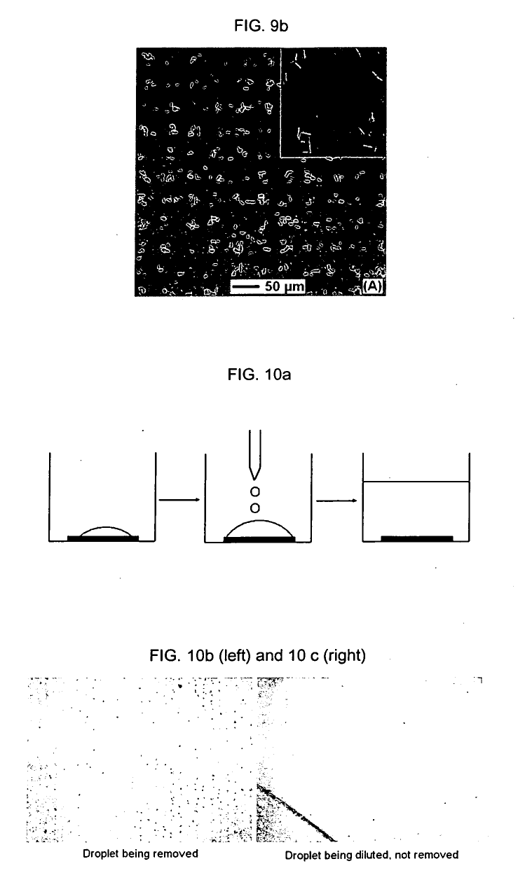

A gold substrate was patterned with hexadecane thiol and the sodium salt of 3-mercapto-1-propanesulfonic acid to design 20 μm hydrophilic/hydrophobic lines on the substrate surface. Pd nanowires coated with mercaptoundecanoic acid were applied to the substrate. The resulting pattern is shown in FIG. 9a. FIG. 9b shows an optical micrograph of Pd/mercaptoundecanoic acid nanowires (length 6 μm, diameter 250 nm) on an Au substrate, patterned with the sodium salt of 3-mercapto-1-propanesulfonic acid (20 μm squares) and hexadecane thiol.

### Example 10

FIG. 10a depicts a nanowire suspension on a substrate being diluted with fluidic medium before being removed. FIGS. 10b and 10c show that patterning of nanowires was not observed if the nanowire suspensions were diluted thousands of times before being removed. This shows that electrostatic attraction between the nanowires and the substrate is not critical for the self-assembly process according to the invention.

### Example 11

Production of an Organic Field Effect Transistor

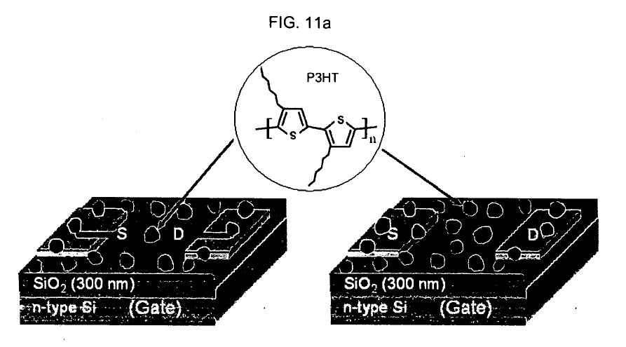

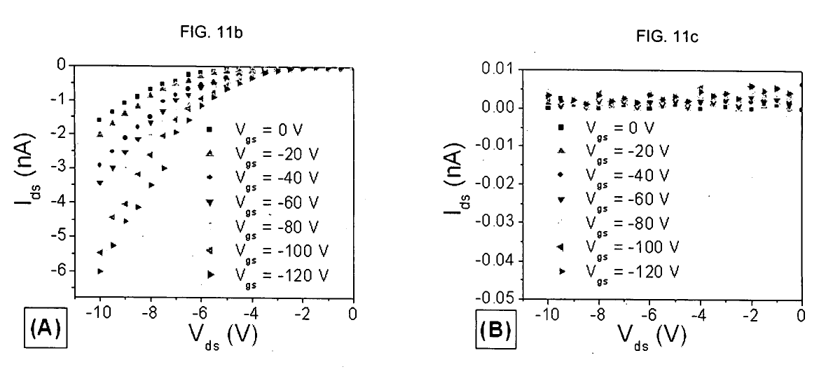

A substrate was prepared using highly doped Si as the gate electrode and thermally grown silicon dioxide (300 nm) as dielectric layer. For the production of an OFET, poly(3-hexylthiophene) crystals were applied to the substrate. FIG. 11a depicts the device structures. S and D correspond to the source and the drain, respectively. The characteristic curves of the obtained transistors are shown in FIGS. 11b and 11c. In the device according to FIG. 11b (A), nanowire electrodes with 100 nm gap are used as the source and drain electrodes. In the device according to FIG. 11b (B) (=comparative example) contact pads without nanowires (channel width W=250 μm, channel length L=4 μm) are used.

We claim:

1. A method of depositing nanowires on the surface of a substrate, comprising the steps of:
contacting defined regions of the substrate with at least one compound (C1) capable of binding to the surface of the substrate and of binding the nanowires to provide a pattern of binding sites on the surface of the substrate and/or contacting defined regions of the substrate with at least one compound (C2) capable of binding to the surface of the substrate and preventing the binding of nanowires to provide a pattern of non-binding sites on the surface of the substrate, and
contacting the surface of the substrate with a suspension of nanowires in a liquid medium to enable at least a portion of the applied nanowires to bind to at least a portion of the surface of the substrate covered with (C1) and/or not covered with (C2).

2. The method as claimed in claim 1, comprising the steps of:
(a) providing a stamp having a surface including a plurality of indentations formed therein defining an indentation pattern, said indentations being contiguous with a stamping surface and defining a stamping pattern,
(b) coating said stamping surface with at least one compound (C1),
(c) contacting at least a portion of the surface of a substrate with said stamping surface to allow deposition of said compound (C1) on the substrate,
(d) removing said stamping surface to provide a pattern of binding sites on the surface of the substrate,
(e) applying the suspension of nanowires to the surface of the substrate to enable at least a portion of the applied nanowires to bind to at least a portion of the binding sites on the surface of the substrate.

3. The method as claimed in claim 2, wherein the substrate with the pattern of binding sites obtained in step d) is contacted with at least one compound (C2) to prevent deposition of the nanowires on areas of the substrate not patterned with compound (C1).

4. The method as claimed in claim 1, comprising the steps of:
(a) providing a stamp having a surface including a plurality of indentations formed therein defining an indentation pattern, said indentations being contiguous with a stamping surface and defining a stamping pattern,
(b) coating said stamping surface with at least one compound (C2),
(c) contacting at least a portion of the surface of a substrate with said stamping surface to allow deposition of said compound (C2) on the substrate,
(d) removing said stamping surface to provide a pattern of sites on the surface of the substrate that prevent binding of nanowires,
(e) applying the suspension of nanowires to the surface of the substrate to enable at least a portion of the applied nanowires to bind to at least a portion of the surface of the substrate not covered with (C2).

5. The method as claimed in claim 4, wherein the substrate obtained in step d) with a pattern of sites on the surface that prevent binding of nanowires is contacted with at least one compound (C1) to allow deposition of the nanowires on areas of the substrate not patterned with compound (C2).

6. The method as claimed in claim 1, wherein nanowires are employed that bear on at least a part of their surface at least one compound (C1) and/or at least one compound (C2).

7. The method as claimed in claim 1, wherein step e) comprises contacting the suspension of nanowires with the surface of the substrate for a period of time sufficient to enable at least a portion of the applied nanowires to bind to at least a portion of the surface and removing the suspension of unbound nanowires from the substrate.

8. The method as claimed in claim 7, wherein the time of contact is in a range of from 30 seconds to 12 hours, preferably from 1 minute to 6 hours, more preferably from 2 minutes to 2 hours.

9. The method as claimed in claim 7, wherein the suspension is removed before the liquid phase of the suspension is completely vaporized.

10. The method as claimed in claim 7, wherein in step e) the suspension of unbound nanowires is removed from the substrate without dilution with a liquid medium.

11. The method as claimed in claim 7, wherein in step e) the suspension of unbound nanowires is drawn off from the substrate by suction, especially with a pipette.

12. The method as claimed in claim 1, wherein a pattern comprising linear binding sites is provided on the surface of the substrate, wherein the breadth of the lines is smaller than the length of the nanowires.

13. The method as claimed in claim 1, wherein the steps of:
contacting defined regions of the substrate with at least one compound (C1) to provide a pattern of binding sites on the surface of the substrate and/or contacting defined regions of the substrate with at least one compound (C2) to provide a pattern of non-binding sites on the surface of the substrate,
contacting the surface of the substrate with a suspension of nanowires in a liquid medium to enable at least a portion of the applied nanowires to bind to at least a portion of the surface of the substrate covered with (C1) and/or not covered with (C2),
are repeated once or a number of times.

14. The method as claimed in claim 13, wherein after each repetition the compounds (C1) with no nanowires bound thereto and/or the compounds (C2) are removed from the substrate.

15. The method as claimed in claim 1 or 13, additionally comprising the steps of:
contacting defined regions of the substrate with at least one compound (C3) capable of binding to the surface of the substrate and of binding at least one organic semiconducting compound (S) and/or contacting defined regions of the substrate with at least one compound (C4) capable of binding to the surface of the substrate and preventing the binding of a compound (S),
applying a compound (S) to the surface of the substrate to enable at least a portion of the applied compound (S) to bind to at least a portion of the surface of the substrate covered with (C3) and/or not covered with (C4).

16. The method as claimed in claim 15, wherein the compound (C3) is selected from the group consisting of compounds (C1) and (C2).

17. The method as claimed in claim 15, wherein the compound (C4) is selected from the group consisting of compounds (C1) and (C2).

18. The method as claimed in claim 15, wherein the organic semiconducting compound (S) is employed in the form of crystallites.

19. The method as claimed in claim 1, wherein liquid medium is selected from water and mixtures of water and at least one water-miscible organic solvent.

20. A method of manufacturing an electronic device comprising the step of providing nanowires on a substrate, comprising the steps of:
contacting defined regions of the substrate with at least one compound (C1) capable of binding to the surface of the substrate and of binding the nanowires to provide a pattern of binding sites on the surface of the substrate and/or contacting defined regions of the substrate with at least one compound (C2) capable of binding to the surface of the substrate and preventing the binding of nanowires to provide a pattern of non-binding sites on the surface of the substrate, and
contacting the surface of the substrate with a suspension of nanowires in a liquid medium to enable at least a portion of the applied nanowires to bind to at least a portion of the surface of the substrate covered with (C1) and/or not covered with (C2).

21. A method as claimed in claim 20, wherein the electronic device comprises a pattern of organic field effect transistors, each transistor comprising:
an organic semiconductor (S) located on the substrate;
a gate structure positioned to control a conductivity of a channel portion of the crystallite; and
conductive source and drain electrodes located at opposite ends of the channel portion,
wherein at least part of the transistors comprise or are interconnected by nanowires obtained by a method as claimed in claim 1.
